(19) United States
(12) Patent Application Publication
(10) Pub. No.: US 2005/0265561 A1
(43) Pub. Date: Dec. 1, 2005

(54) Method and apparatus to generate harmonics in speaker reproducing system

(76) Inventors: Arora Manish, Suwon-si (KR); Hae-kwang Park, Seoul (KR); Yoon-hark Oh, Suwon-si (KR)

Correspondence Address: STANZIONE & KIM, LLP, 919 18TH STREET, N.W., SUITE 440, WASHINGTON, DC, 20006, US

(21) Appl. No.: 11/124,035

(22) Filed: May 9, 2005

(30) Foreign Application Priority Data
May 28, 2004 (KR) 2004-38181

(51) Int. Cl. H03G 3/00; H04H 5/00

(52) U.S. Cl. 381/61; 381/98

(57) ABSTRACT

A method and apparatus to generate harmonics. The method of generating the harmonics includes selecting a first coefficient and a second coefficient according to a result of comparing a level of an input frequency signal and a level of a feedback signal, adding a result of multiplying the level of the input frequency signal by the first coefficient and a result of multiplying the level of the feedback signal by the second coefficient to calculate the level of an output frequency signal, delaying the output frequency signal having the calculated level by a predetermined sample, and transmitting a resulting level of the delayed output frequency signal as the level of the feedback signal.

### CROSS-REFERENCE TO RELATED APPLICATIONS

This application claims the priority of Korean Patent Application No. 2004-38181, filed on May 28, 2004, in the Korean Intellectual Property Office, the disclosure of which is incorporated herein in its entirety by reference.

### BACKGROUND OF THE INVENTION

1. Field of the Invention

The present general inventive concept relates to a method and apparatus to generate harmonics in a speaker reproducing system, and more particularly, to a method and apparatus to generate harmonics in a speaker reproducing system using a modified envelope detection method and apparatus.

2. Description of the Related Art

In a case of large sized speakers connected to personal computers (PC) or TVs, high producing costs are required to produce the large sized speakers. As a result, a size of a speaker is limited. According to an improved performance of audio equipment, the size of the speaker has been reduced. However, due to the limited size of the speaker, the performance of bass sound reproduction can not be improved.

For high-performance reproduction of low-frequency sounds, psychoacoustic techniques have been recently used in speaker reproducing systems. The psychoacoustic techniques are utilized to shift bass frequencies to mid frequency regions where a transducer response is good. The psychoacoustic techniques require generation of harmonics. Thus, harmonic generation methods directly relate to an improvement of performance of a low-frequency or bass sound reproduction using the psychoacoustic techniques.

FIG. 1 is a waveform illustrating an input frequency signal used for generating harmonics and output harmonic signals in a conventional speaker reproducing system. Referring to FIG. 1, a sine-wave input frequency signal 110 used for generating the harmonics, an output frequency signal 120 obtained by performing a full wave rectification on the input frequency signal 110, and a second output frequency signal 130 obtained by performing a full wave integration on the input frequency signal 110 are shown.

FIG. 2 is a graph illustrating spectrums of the input frequency signal 110 and the first and second output frequency signals 120 and 130 that are shown in FIG. 1. Referring to FIGS. 1 and 2, a spectrum 210 of the sine-wave input frequency signal 110, harmonic spectrums 220 of the output frequency signal 120 using the full wave rectification, and harmonic spectrums 230 of the output frequency signal 130 using the full wave integration are shown.

FIG. 3 is a block diagram illustrating an apparatus for improving psychoacoustic bass sounds in a conventional speaker reproducing system.

A first multiplier 315 multiplies a low-frequency signal 310 by a feedback signal that is delayed by a one-sample delay unit 355. The first multiplier 315 generates (N+1)^{th} harmonics from all the N^{th} harmonics of the feedback signal before multiplied. An adder 320 adds the low-frequency signal 310 and an output of the first multiplier 315. The adder 320 outputs a result of the addition to a feedback high-pass filter 340 of a feedback loop. An output high-pass filter 325 filters an output of the adder 320. At this time, the high-pass filter 325 controls allowable frequencies such that frequencies below f₃ are not output.

An upward compressor logic 330 generates a control signal that controls dynamic gains. The control signal generated by the upward compressor logic 330 depends on the energy envelope of a signal output from the output high-pass filter 325. A second multiplier 335 multiplies the output of the output high-pass filter 325 by an output of the upward compressor logic 330 and outputs a result of the multiplication as a psychoacoustic signal 360.

In the feedback loop, the feedback high-pass filter 340 filters a signal that is output from the adder 320. At this time, the feedback high-pass filter 340 cuts out frequencies below a cut-off frequency f₁. A third multiplier 350 multiplies the control signal output from the upward compressor logic 330 by an output of an amplifier 345. The one-sample delay unit 355 delays a signal output from the third multiplier 350 by one sample and outputs the delayed signal to the first multiplier 315 as the feedback signal.

Conventional methods for generating the harmonics, as shown in FIGS. 1 through 3, cannot control the envelope of the spectrum of a harmonic signal. An attenuation rate of high-order harmonics is an important factor because it controls tone quality of perceived bass sounds. Thus, a method of generating harmonics is required to effectively control amplitudes of harmonics and the attenuation rate of the spectrum of high-order harmonics.

Also, the conventional methods for generating the harmonics are dependent on a level of an input frequency signal. Spectrum envelopes vary according to the level of the input frequency signal, causing a problem when the level of the input frequency signal is low. Since a signal may decrease or increase and a location of a bass sound improving block is not fixed in a signal path, a method of generating harmonics should be independent of the level of the input frequency signal.

The conventional methods for generating the harmonics require difficult computation and are hard to implement in the conventional reproduction system. The full wave rectification described with reference to FIG. 1 is a simple way to generate the harmonics. However, since only even-numbered harmonics are generated as shown in FIG. 2, a pitch of the harmonics perceived by the psychoacoustic techniques is not f₀ but 2f₀.

### SUMMARY OF THE INVENTION

The present general inventive concept provides a method of generating harmonics, which controls an envelope of a spectrum of a harmonic signal by generating the harmonics from an input frequency signal using a modified envelope detection method in a speaker reproducing system.

The present general inventive concept also provides an apparatus to generate harmonics, which controls an envelope of a spectrum of a harmonic signal by generating the harmonics from an input frequency signal using a modified envelope detection apparatus in a speaker reproducing system.

Additional aspects and advantages of the present general inventive concept will be set forth in part in the description which follows and, in part, will be obvious from the description, or may be learned by practice of the general inventive concept.

The foregoing and/or other aspects and advantages of the present general inventive concept may be achieved by providing a method of generating harmonics in a speaker reproducing system, the method including comparing a level of an input frequency signal and a level of a feedback signal level, selecting a first coefficient and a second coefficient to determine a waveform of an output frequency signal based on a result of the comparison and calculating a level of the output frequency signal based on the selected coefficients, and delaying the output frequency signal having the calculated level by a predetermined sample and transmitting a resulting level of the delayed output frequency signal as the level of the feedback signal.

The foregoing and/or other aspects and advantages of the present general inventive concept may also be achieved by providing an apparatus to generate harmonics in a speaker reproducing system. The apparatus includes a comparing unit to compare a level of an input frequency signal and a level of a feedback signal level, a coefficient selecting unit to select a first coefficient and a second coefficient to determine a waveform of an output frequency signal based on a result of the comparison of the comparing unit, a first multiplying unit to multiply the level of the input frequency signal by the selected first coefficient, a second multiplying unit to multiply the level of the feedback signal by the selected second coefficient, an adding unit to add a result of the multiplication of the first multiplying unit and a result of the multiplication of the second multiplying unit to calculate a level of the output frequency signal and to output the calculated level of the output frequency signal, and a sample delay unit to delay the output frequency signal having the calculated level by a predetermined sample and to transmit a resulting level of the delayed output frequency signal as the level of the feedback signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a waveform illustrating an input frequency signal used for generation of harmonics and output harmonic signals in a conventional speaker reproducing system;

FIG. 2 is a graph illustrating spectrums of the input frequency signal and the output frequency signals that are shown in FIG. 1;

FIG. 3 is a block diagram illustrating an apparatus generating psychoacoustic bass sounds in a conventional speaker reproducing system;

FIG. 4 is a block diagram illustrating an apparatus to generate harmonics according to an embodiment of the present general inventive concept;

FIG. 5 is a flowchart illustrating a method of generating the harmonics in the apparatus of FIG. 4;

FIG. 6A is a waveform of an input signal for generation of harmonics in the method of FIG. 5;

FIGS. 6B through 6E are waveforms illustrating output signals with respect to the input signal of FIG. 6A;

FIG. 7A is a graph illustrating a spectrum of the input signal of FIG. 6A;

FIGS. 7B through 7E are graphs illustrating spectrums of the output signals of FIGS. 6B through 6E;

FIG. 8 is a block diagram illustrating an apparatus to generate harmonics according to another embodiment of the present general inventive concept;

FIG. 9 is a flowchart illustrating a method of generating the harmonics in the apparatus of FIG. 8;

FIG. 10 is a waveform illustrating an input frequency signal and an output frequency signal in the method of FIG. 9; and

FIG. 11 is a graph illustrating a spectrum of the output frequency signal of FIG. 10.

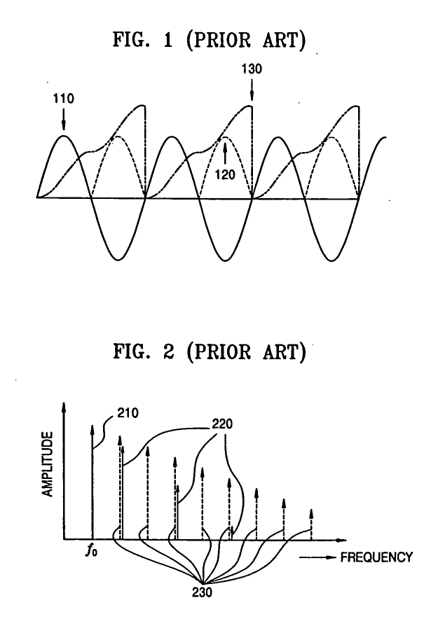

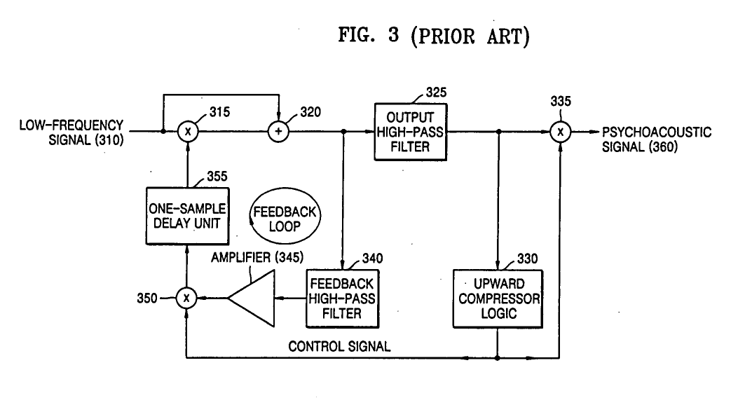

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures.

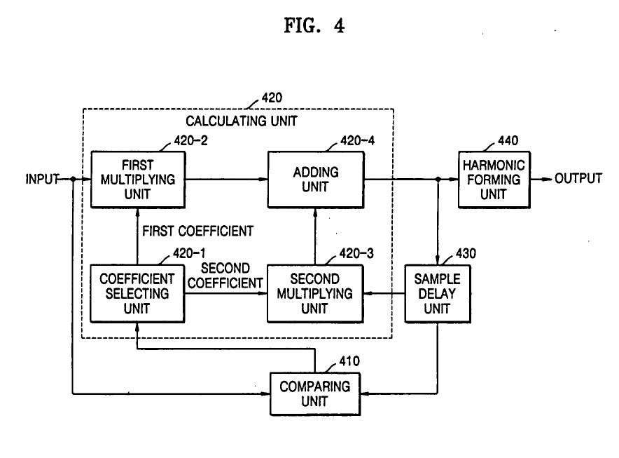

FIG. 4 is a block diagram illustrating an apparatus to generate harmonics according to an embodiment of the present general inventive concept. The apparatus to generate the harmonics includes a comparing unit 410, a calculating unit 420, a sample delay unit 430, and a harmonic forming unit 440.

The comparing unit 410 receives a level of an input frequency signal and a level of a feedback signal and compares the two levels.

The calculating unit 420 includes a coefficient selecting unit 420-1, a first multiplying unit 420-2, a second multiplying unit 420-3, and an adding unit 420-4.

The coefficient selecting unit 420-1 selects a first coefficient and a second coefficient to determine a waveform of an output frequency signal according to a result of the comparison of the comparing unit 410.

For example, it is assumed that when the level of the feedback signal is less than that of the input frequency signal, the selected first coefficient and second coefficient are set to α and (1−α), respectively. Also, it is assumed that when the level of the feedback signal is not less than that of the input frequency signal, the selected first coefficient and second coefficient are set to β and (1−β), respectively. That is, when the level of the feedback signal is less than that of the input frequency signal as a result of the comparison of the comparing unit 410, α is selected as the first coefficient and (1−α) is selected as the second coefficient. When the level of the feedback signal is greater than or equal to that of the input frequency signal as a result of the comparison of the comparing unit 410, β is selected as the first coefficient and (1−β) is selected as the second coefficient.

As described above, the first coefficient and the second coefficient may be set such that a sum thereof is equal to zero. Also, the first coefficient and the second coefficient may be set such that the sum thereof is greater than or equal to 0 and less than or equal to 1.

The first multiplying unit 420-2 multiplies the level of the input frequency signal by the selected first coefficient.

The second multiplying unit 420-3 multiplies the level of the feedback signal by the selected second coefficient.

The adding unit 420-4 adds results of the multiplication of the first multiplying unit 420-2 and second multiplying unit 420-3 to generate a level of an output frequency signal. The adding unit 420-4 outputs the generated level of the output frequency signal.

The level of the output frequency signal, which is generated by the adding unit 420-4, forms a waveform of a frequency signal including harmonic components of the input frequency signal. Therefore, the output of the adding unit 420-4 is an output of the apparatus to generate the harmonics.

Also, the level of the output frequency signal, which is generated by the adding unit 420-4, forms a modified envelope of the input frequency signal. Therefore, the output of the adding unit 420-4 is an output of a modified envelope detection apparatus to generate the harmonics.

The sample delay unit 430 delays the level of the output frequency signal, which is generated by the adding unit 420-4, by a predetermined sample and transmits a resulting level as the level of the feedback signal. For example, the sample delay unit 430 delays the level of the output frequency signal, which is generated by the adding unit 420-4, by one sample and transmits a resulting level as the level of the feedback signal. The transmitted level of the feedback signal is compared with the level of the input frequency signal by the comparing unit 410 and is multiplied by the second coefficient by the second multiplying unit 420-3.

The harmonic forming unit 440 receives the level of the output frequency signal, which is generated by the adding unit 420-4, and forms the waveform of the output frequency signal that is obtained using the first coefficient and the second coefficient. The formed output frequency signal includes harmonic components of the input frequency signal.

The level of the formed output frequency signal may have a positive gradient when calculated using the first coefficient of α and the second coefficient of (1−α). However, the level of the formed output frequency signal may have a negative gradient when calculated using the first coefficient of β and the second coefficient of (1−β).

Also, the formed output frequency signal needs more time to rise as α is set larger, and needs more time to fall as β is set larger. In other words, the first coefficient and the second coefficient determine the waveform of the output frequency signal including harmonic components of the input frequency signal.

The harmonic forming unit 440 outputs a spectrum of the waveform of the formed output frequency signal. The output spectrum includes harmonic components of the input frequency signal. The first coefficient and the second coefficient control the envelope of the spectrum. The harmonic forming unit 440 forms harmonics of psychoacoustic effects required for bass sound enhancement.

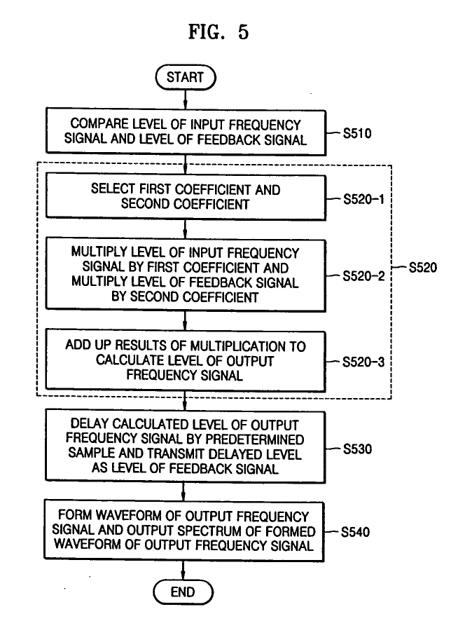

FIG. 5 is a flowchart illustrating a method of generating the harmonics in the apparatus of FIG. 4.

Referring to FIGS. 4 and 5, the level of the input frequency signal and the level of the feedback signal are compared in a comparison operation S510.

In a calculation operation S520, predetermined coefficients that determine the waveform of the output frequency signal are determined (selected) according to a result of the comparison obtained in the comparison operation S510. Then, the level of the output frequency signal is calculated based on the selected coefficients.

The calculation operation S520 includes a coefficient selection operation S520-1, a multiplication operation S520-2, and an adding operation S520-3.

In the coefficient selection operation S520-1, predetermined first coefficient and second coefficient are selected according to the result of the comparison obtained in the comparison operation S510.

In the multiplication operation S520-2, the first coefficient and the level of the input frequency signal are multiplied and the second coefficient and the level of the feedback signal are multiplied.

In the adding operation S520-3, results of the multiplication obtained in the multiplication operation S520-2 are added to calculate the level of the output frequency signal. The level of the output frequency signal, which is obtained in the adding operation S520-3, forms a waveform of an output frequency signal including harmonic components of the input frequency signal. Thus, the output obtained in the adding operation S520-3 is an output obtained using the method of generating harmonics.

Also, the level of the output frequency signal, which is obtained in the adding operation S520-3, forms a modified envelope of the input frequency signal. Thus, the output obtained in the adding operation S520-3 is an output obtained using a modified envelope detection method.

In a sampling delay operation S530, the level of the output frequency signal, which is obtained in the adding operation S520-3, is delayed by a predetermined sample, and then a resulting level of the delayed output frequency signal is transmitted as the level of the feedback signal.

In a harmonic forming operation S540, the level of the output frequency signal, which is obtained in the adding operation S520-3, is input and the waveform of the output frequency signal that is obtained using the first coefficient and the second coefficient is formed. The formed output frequency signal includes harmonic components of the input frequency signal.

The spectrum of the waveform of the output frequency signal formed in the harmonic forming operation S540 is output. The output spectrum includes the harmonic components of the input frequency signal, and the first coefficient and the second coefficient control the envelope of the output spectrum.

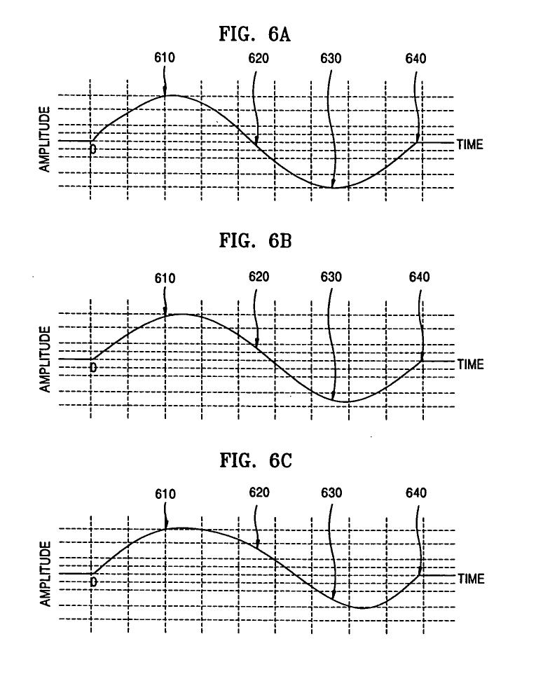

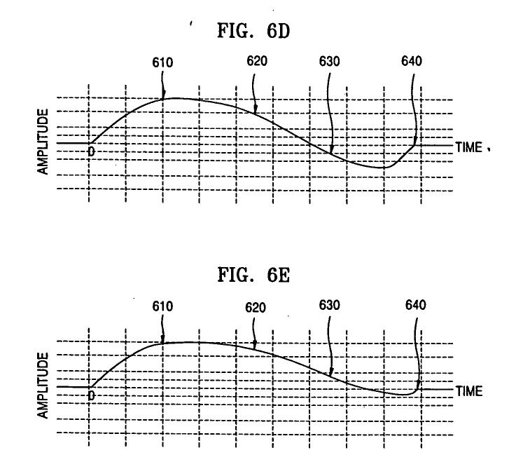

FIG. 6A is a waveform of an input signal to generate the harmonics in the method of FIG. 5 and shows a single cycle of a 50 Hz sine wave as an example of the input signal.

FIGS. 6B through 6E are waveforms of output signals with respect to the input signal of FIG. 6A. The waveforms of the output signals have fast rising times but slow falling times. The fast rising times are all 0.1 msec. The slow falling times are all set to 1 msec in FIG. 6B, to 3 msec in FIG. 6C, to 5 msec in FIG. 6D, and to 10 msec in FIG. 6E. The rising time and falling time can be controlled by adjusting the first coefficient and the second coefficient.

Referring to FIGS. 6B through 6E, since the rising times are fast, the output signals follow the input signal until a point 610. The output signals fall depending on the falling times from the point 610 to a point 620. The output signals continuously fall and then begin to rapidly rise at a point where the output signals are below the input signal. The falling times should be enough to complete falling before a next cycle of the input signal starts. The output signals have positive gradients and match the input signal, at zero intersections including a point 640. Thus, according to the modified envelope detection method, a fundamental frequency is maintained, and harmonics are generated along with the fundamental frequency.

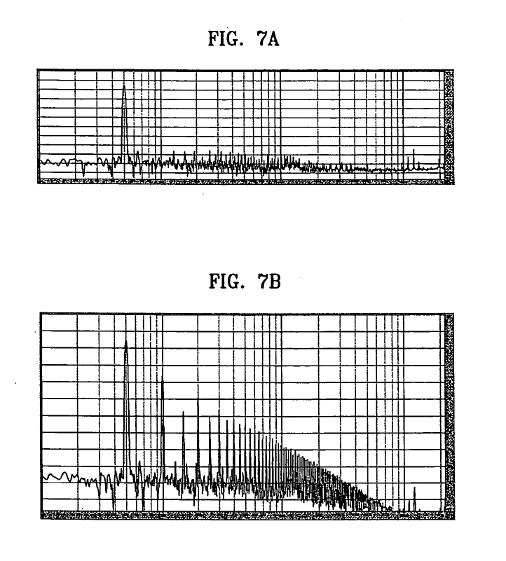

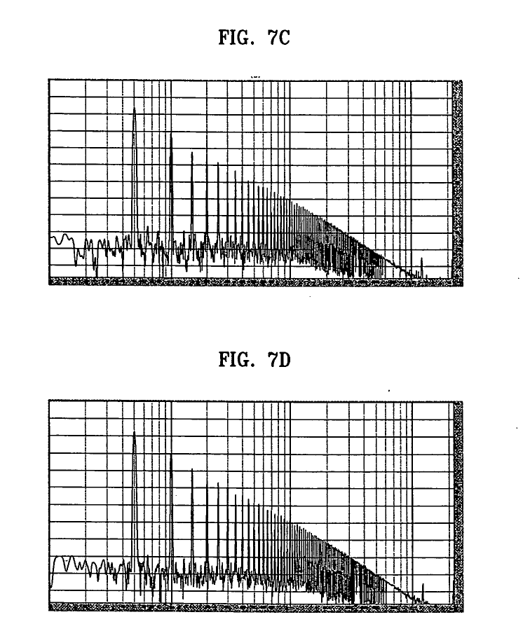

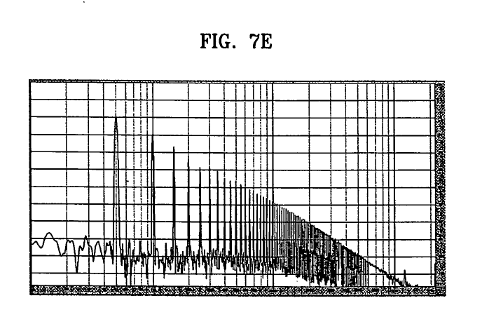

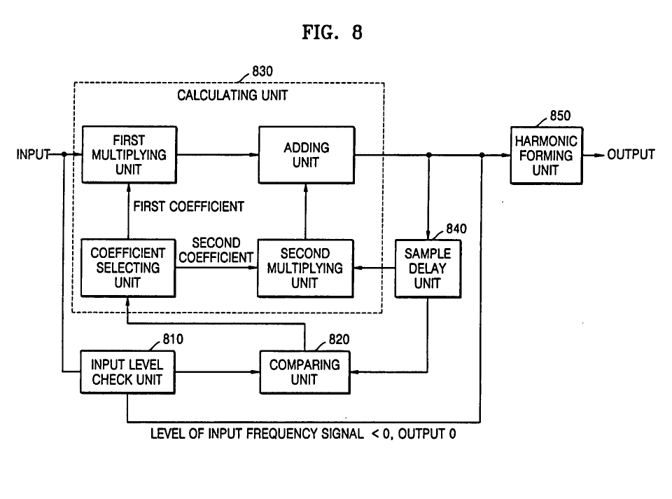

FIG. 7A is a graph illustrating a spectrum of the input signal of FIG. 6A. FIGS. 7B through 7E are graphs illustrating spectrums of the output signals of FIGS. 6B through 6E, in which the spectrums of harmonics output in the harmonic forming operation S540 are shown. Referring to FIGS. 7B through 7E, even-numbered harmonics and odd-numbered harmonics are all generated. Also, changes in the falling times control the envelope of the spectrums of the harmonics.

Referring to FIGS. 6A through 6E and FIGS. 7A through 7E, at all levels of the input frequency signal, the output spectrums show the similar form independently regardless of the levels of the input frequency signal. Thus, the envelope of the spectrums of the output frequency signals is independent of the level of the input frequency signal.

Table 1 shows pseudo codes to generate the harmonics in the method of FIG. 5.

TABLE 1

IF Last Output is Less than Input
Output=Last Output*α+Input*[1−α]
ELSE
Output=Last Output*β+Input*[1−β]
END

FIG. 8 is a block diagram illustrating an apparatus to generate harmonics according to another embodiment of the present general inventive concept. The apparatus to generate the harmonics includes an input level checking unit 810, a comparing unit 820, a calculating unit 830, a sample delay unit 840, and a harmonic forming unit 850.

The comparing unit 820, the calculating unit 830, the sample delay unit 840, and the harmonic forming unit 850 are similar to the comparing unit 410, the calculating unit 420, the sample delay unit 430, and the harmonic forming unit 440 of FIG. 4, respectively.

The input level checking unit 810 checks if a level of an input frequency signal is a negative number or in a negative state. If the level of the input frequency signal is the negative number or in the negative state, the input level checking unit 810 causes a level of an output frequency signal, which is output from the calculating unit 830, to be zero. Thus, when the level of the input frequency signal is the negative number or in the negative state, zero is input to the sample delay unit 830 and the harmonic forming unit 840. Also, when the level of the input frequency signal is the negative number or in the negative state, the comparing unit 820 and the calculating unit 830 may not operate.

The level of the output frequency signal that is set to zero by the input level checking unit 810 forms the waveform of the output frequency signal including harmonic components of the input frequency signal. Thus, the output frequency signal that contains zero set by the input level checking unit 810 is the output of the apparatus to generate the harmonics.

Also, the level of the output frequency signal that is set to zero by the input level checking unit 810 forms a modified envelope of the input frequency signal. Thus, the output frequency signal that contains zero set by the input level checking unit 810 is the output of the modified envelope detection apparatus.

An apparatus to generate the harmonics according to this embodiment of the present general inventive concept generates stronger and higher harmonics. Also, an energy of the fundamental frequency may be lower than that in the apparatus of FIG. 4.

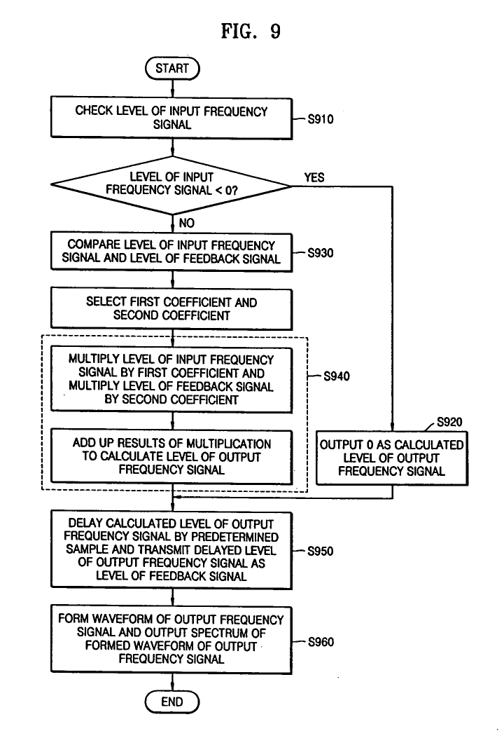

FIG. 9 is a flowchart illustrating a method of generating the harmonics in the apparatus of FIG. 8.

A comparison operation S930, a calculation operation S940, a sample delay operation S950, and a harmonic formation operation S960 are similar to the comparison operation S510, the calculation operation S520, the sample delay operation S530, and the harmonic forming operation S540 of FIG. 5, respectively.

In an input level check operation S910, it is checked if the level of the input frequency signal is a negative number or on a negative state. If the level of the input frequency signal is the negative number or in the negative state, the level of the output frequency signal, which is calculated in the calculation operation S940, is set to zero in operation S920. Thus, when the level of the input frequency signal is a negative number, zero is delayed by a predetermined sample in the sample delay operation S950 and is input in the harmonic formation operation S960, and the waveform of the output frequency signal is formed. Also, when the level of the input frequency signal is the negative number or in the negative state, the comparison operation S930 and the calculation operation S940 may be skipped.

The level of the output frequency signal that is set to zero in the input level check operation S910 forms the waveform of the output frequency signal including harmonic components of the input frequency signal. Thus, the output frequency signal that contains zero that is set in the input level check operation S910 is the output obtained using the method of generating the harmonics.

Also, the level of the output frequency signal that is set to zero in the input level check operation S910 forms the modified envelope of the input frequency signal. Thus, the output frequency signal that contains zero that is set in the input level check operation S910 is the output obtained using the modified envelope detection method.

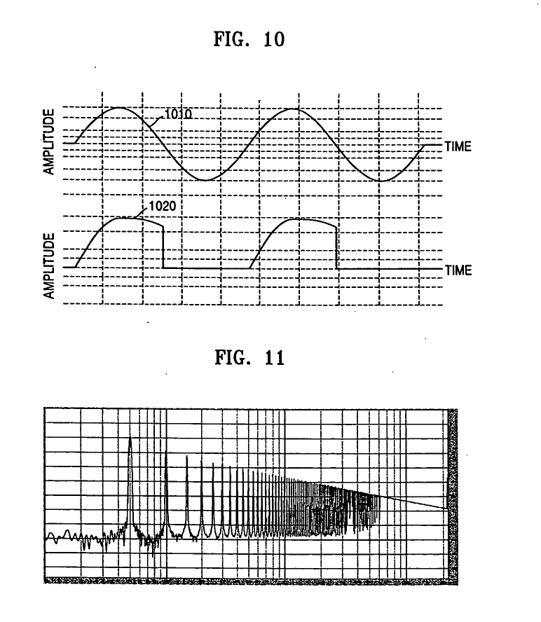

FIG. 10 is a waveform of the input frequency signal and the output frequency signal of FIG. 9. Referring to FIG. 10, when a level of an output frequency 1010 is a positive number or in a positive state, a level of an output frequency signal 1020 is generated according to the method of FIG. 5 or FIG. 9. However, when the level of the input frequency signal 1010 is a negative number or in a negative state, the level of the output frequency signal 1020 is set to zero and the level of the output frequency signal 1020 is maintained at zero until the level of the input frequency signal 1010 becomes the positive number or the positive state. Once the level of the input frequency signal 1010 becomes the negative number or the negative state, the level of the output frequency signal 1020 drops to zero, so that strong harmonics are generated. That is, the input frequency signal may have a period including a first rising time and a first falling time between the positive state and the negative state, and the lever of the output frequency signal may have the same period including a second rising time and a second rising time between the positive state and the negative state so that the second rising time is faster than the first rising time, and the second falling time is slower than the first falling time as shown in FIGS. 6A through 6E. As an example, when the input frequency signal has a first positive state and a first negative state, and the output frequency signal may have a second positive state having a faster rising time than that of first positive state of the input frequency signal, and a second negative state different from the first negative state. The second negative state may be a constant state or a zero state as shown in FIG. 10.

FIG. 11 is a graph illustrating a spectrum of the output frequency signal 1020 of FIG. 10. Referring to FIG. 11, a spectrum of harmonics that are generated in the harmonic forming operation S960 is shown.

Table 2 shows pseudo codes to generate the harmonics in the method of FIG. 9.

TABLE 2

IF Input is Greater than Zero
IF Last Output is Less than Input
Output=Last Output*α+Input*[1−α]
ELSE
Output=Last Output*β+Input*[1−β]
END
ELSE
Output=0
END

As described above, both even-numbered and odd-numbered harmonics can be generated. Also, it is possible to control the envelope of the spectrum of a harmonic signal. The method and apparatus to generate the harmonics, which may be independent from the level of an input frequency signal, is provided. Thus, it is possible to enhance the performance of reproduction of low-frequency sounds and bass sounds by introducing the present invention to psychoacoustic signal generation to improve the performance of bass sound reproduction.

Conventional methods for generating harmonics using a conventional feedback have difficulties in generating high-order harmonics from an input frequency signal of a very low level. However, by adopting the present general inventive concept, generated harmonics are mutually modulated with harmonics that are generated from a next sample of the input frequency signal. As a result, sufficient harmonics including high harmonics that are hard to obtain at a low signal level can be generated. Therefore, it is possible to generate high-order harmonics from an input signal of a very low level, thereby improving the performance of a feedback of the conventional methods for generating harmonics.

The present general inventive concept can also be embodied as a computer readable code on a computer-readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves. The computer readable recording medium can also be distributed over network coupled computer systems so that the computer readable code is stored and executed in a distributed fashion.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A method of generating harmonics in a speaker reproducing system, the method comprising:
comparing a level of an input frequency signal and a level of a feedback signal;
selecting a first coefficient and a second coefficient to determine a waveform of an output frequency signal according to a result of the comparison, and calculating a level of the output frequency signal according to the selected first and second coefficients; and
delaying the output frequency signal having the calculated level by a predetermined sample, and transmitting a resulting level of the delayed output frequency signal as the level of the feedback signal.

2. The method of claim 1, wherein the calculating of the level of the output frequency signal comprises adding a result of multiplying the level of the input frequency signal by the selected first coefficient and a result of multiplying the level of the feedback signal by the selected second coefficient.

3. The method of claim 2, wherein a sum of the first coefficient and second coefficient is equal to zero.

4. The method of claim 1, further comprising:
receiving the calculated level of the output frequency signal, forming the waveform of the output frequency signal, and outputting a spectrum of the formed waveform of the output frequency signal.

5. The method of claim 1, wherein the calculating of the level of the output frequency signal comprises setting the calculated level of the output frequency signal to zero if the level of the input frequency signal is a negative number.

6. The method of claim 1, wherein the selecting of the first coefficient and the second coefficient comprises:
selecting one of a first state and a second state as the first coefficient according to the result of the comparison; and
selecting one of a third state and a fourth state as the second coefficient according to the result of the comparison.

7. The method of claim 6, wherein the first state, the second state, the third state, and the fourth state are different from one another.

8. The method of claim 6, wherein the selecting of the one of the first state and the second state comprises:
selecting the one of the first state and the second state as the first coefficient according to a difference between the level of the input frequency signal and the level of the feedback signal level.

9. The method of claim 6, wherein the selecting of the one of the third state and the fourth state comprises:
selecting the one of the third state and the fourth state as the second coefficient according to a difference between the level of the input frequency signal and the level of the feedback signal level.

10. The method of claim 6, wherein a sum of the first state and the third state is equal to a predetermined number, and a sum of the second state and the fourth state is equal to the predetermined number.

11. The method of claim 1, wherein the calculating of the level of the output frequency signal comprises:
generating a first signal according to the input frequency signal and the first coefficient;
generating a second signal according to the feedback signal and the second coefficient; and
generating a third signal corresponding to the level of the output frequency signal according to the first signal and the second signal.

12. An apparatus to generate harmonics in a speaker reproducing system, the apparatus comprising:
a comparing unit to compare a level of an input frequency signal and a level of a feedback signal level;
a calculating unit to select a first coefficient and a second coefficient to determine a waveform of an output frequency signal according to a result of the comparison of the comparing unit, and to calculate a level of the output frequency signal according to the selected first and second coefficients; and
a sample delay unit to delay the output frequency signal having the calculated level by a predetermined sample, and to transmit a resulting level of the delayed output frequency signal as the level of the feedback signal.

13. The apparatus of claim 12, wherein the calculating unit comprises:
a first multiplying unit to multiply the level of the input frequency signal by the selected first coefficient;
a second multiplying unit to multiply the level of the feedback signal by the selected second coefficient; and
an adding unit to add a result of the multiplication of the first multiplying unit and a result of the multiplication of the second multiplying unit to calculate the level of the output frequency signal and to output the calculated level of the output frequency signal.

14. The apparatus of claim 12, further comprising:
an input level check unit to check if the level of the input frequency signal is a negative number, and to set the calculated level of the output frequency signal to zero if the level of the input frequency signal is the negative number.

15. The apparatus of claim 12, wherein the calculating unit selects one of a first state and a second state as the first coefficient according to the result of the comparison of the comparing unit; and
selecting one of a third state and a fourth state as the second coefficient according to the result of the comparison of the comparing unit.

16. The apparatus of claim 15, wherein the first state, the second state, the third state, and the fourth state are different from one another.

17. The apparatus of claim 15, wherein the calculating unit selects the one of the first state and the second state as the first coefficient according to a difference between the level of the input frequency signal and the level of the feedback signal level, and selects the one of the third state and the fourth state as the second coefficient according to the difference between the level of the input frequency signal and the level of the feedback signal level.

18. The apparatus of claim 15, wherein a sum of the first state and the third state is equal to a predetermined number, and a sum of the second state and the fourth state is equal to the predetermined number.

19. The apparatus of claim 12, wherein the calculating unit generates a first signal according to the input frequency signal and the first coefficient, generates a second signal according to the feedback signal and the second coefficient, and generates a third signal corresponding to the level of the output frequency signal according to the first signal and the second signal.

20. A computer-readable recording medium comprising computer readable codes to perform a method of generating harmonics in a speaker reproducing system, the method comprising:
comparing a level of an input frequency signal and a level of a feedback signal level;
selecting a first coefficient and a second coefficient to determine a waveform of an output frequency signal according to a result of the comparison, and calculating a level of the output frequency signal according to the selected first and second coefficients; and
delaying the output frequency signal having the calculated level by a predetermined sample, and transmitting a resulting level of the delayed output frequency signal as the level of the feedback signal.

21. A method of generating harmonics in a speaker reproducing system, the method comprising:
determining a first and a second coefficients according to an input frequency signal which comprises a period including a first rising time and a first falling time between a positive state and a negative state, and a level of an output frequency signal of the input frequency signal; and
generating the output frequency signal having the period including a second rising time and a second rising time between the positive state and the negative state.

22. The method of claim 21, wherein the determining of the first and second coefficients comprises:
comparing a level of the input frequency signal and a level of a feedback signal as the level of the output frequency signal;
selecting the first coefficient and the second coefficient to determine a waveform of the output frequency signal according to a result of the comparison, and calculating the level of the output frequency signal according to the selected first and second coefficients; and
delaying the output frequency signal having the calculated level by a predetermined sample, and transmitting a resulting level of the delayed output frequency signal as the level of the feedback signal

23. The method of claim 21, wherein the second rising time is faster than the first rising time, and the second falling time is slower than the first falling time.

24. The method of claim 21, wherein the input frequency signal comprises a first positive state and a first negative state, and the output frequency signal comprises a second positive state having a faster rising time than that of first positive state of the input frequency signal, and a second negative state different from the first negative state.

25. The method of claim 24, wherein the second negative state is equal to a constant state between the first positive state and the first positive state.

26. The method of claim 25, wherein the constant state is a zero state.

27. The method of claim 21, further comprising:
forming a harmonic signal having a waveform of harmonics having harmonics frequency of n*fo where a frequency of the input frequency signal is fo and n is an integer, according to the level of the output frequency signal.

28. An apparatus to generate harmonics in a speaker reproducing system, the apparatus comprising:
a calculating unit to determine a first and a second coefficients according to an input frequency signal which comprises a period including a first rising time and a first falling time between a positive state and a negative state, and a level of an output frequency signal of the input frequency signal, and to generate the output frequency signal having the period including a second rising time and a second rising time between the positive state and the negative state.

29. The apparatus of claim 28, further comprising:
a comparing unit to compare a level of the input frequency signal and a level of a feedback signal as the level of the output frequency signal so that the calculating unit selects the first coefficient and the second coefficient to determine a waveform of the output frequency signal according to a result of the comparison and calculates the level of the output frequency signal according to the selected first and second coefficients, and
a delay unit to delay the output frequency signal having the calculated level by a predetermined sample, and transmitting a resulting level of the delayed output frequency signal as the level of the feedback signal.

30. The apparatus of claim 28, wherein the second rising time is faster than the first rising time, and the second falling time is slower than the first falling time.

31. The apparatus of claim 28, wherein the input frequency signal comprises a first positive state and a first negative state, and the output frequency signal comprises a second positive state having a faster rising time than that of first positive state of the input frequency signal, and a second negative state different from the first negative state.

32. The apparatus of claim 31, wherein the second negative state is equal to a constant state between the first positive state and the first positive state.

33. The apparatus of claim 32, wherein the constant state is a zero state.

34. The apparatus of claim 28, further comprising:
a harmonic forming unit to form a harmonic signal having a waveform of harmonics having harmonics frequency of n*fo where a frequency of the input frequency signal is fo and n is an integer, according to the level of the output frequency signal.

35. A computer-readable recording medium comprising computer readable codes to perform a method of generating harmonics in a speaker reproducing system, the method comprising:
determining a first and a second coefficients according to an input frequency signal which comprises a period including a first rising time and a first falling time between a positive state and a negative state, and a level of an output frequency signal of the input frequency signal; and
generating the output frequency signal having the period including a second rising time and a second rising time between the positive state and the negative state.

36. The computer-readable recording medium of claim 35, wherein the determining of the first and second coefficients comprises:
comparing a level of the input frequency signal and a level of a feedback signal as the level of the output frequency signal;
selecting the first coefficient and the second coefficient to determine a waveform of the output frequency signal according to a result of the comparison, and calculating the level of the output frequency signal according to the selected first and second coefficients; and
delaying the output frequency signal having the calculated level by a predetermined sample, and transmitting a resulting level of the delayed output frequency signal as the level of the feedback signal

37. The computer-readable recording medium of claim 36, wherein the second rising time is faster than the first rising time, and the second falling time is slower than the first falling time.

38. The computer-readable recording medium of claim 36, wherein the method further comprises:
forming a harmonic signal having a waveform of harmonics having harmonics frequency of n*fo where a frequency of the input frequency signal is fo and n is an integer, according to the level of the output frequency signal.
